(19) United States
(12) Patent Application Publication
(10) Pub. No.: US 2012/0309133 A1
(43) Pub. Date: Dec. 6, 2012

(54) ELECTRONIC COMPONENT MOUNTING METHOD

(75) Inventors: Yoshiyuki Wada, Osaka (JP); Tadahiko Sakai, Osaka (JP); Tsubasa Saeki, Osaka (JP); Hironori Munakata, Osaka (JP); Koji Motomura, Osaka (JP)

(73) Assignee: PANASONIC CORPORATION, Osaka (JP)

(21) Appl. No.: 13/578,021

(22) PCT Filed: Sep. 26, 2011
(86) PCT No.: PCT/JP2011/005367

§ 371 Date: Aug. 9, 2012

(30) Foreign Application Priority Data
Sep. 27, 2010 (JP) 2010-214878

(51) Int. Cl. H01L 21/60

(52) U.S. Cl. 438/124; 257/E21.506

(57) ABSTRACT

A method of mounting an electronic component allows bumps to land onto electrodes via thermosetting flux formed of first thermosetting resin containing a first active ingredient, and brings a resin reinforcing member formed of second thermosetting resin containing a second active ingredient into contact with the electronic component at reinforcement sections, and then heats the substrate to form solder junction sections that bond the bumps to the electrodes. At the same time, the method forms resin reinforcement sections that reinforce the solder junction sections from the surroundings. A mixing ratio of the second active ingredient in the resin reinforcing member is set greater than a mixing ratio of the first active ingredient in the thermosetting flux.

### TECHNICAL FIELD

The present invention relates to a method of mounting an electronic component, having a bump containing solder and formed on its underside, to an electrode formed on a substrate by solder joint.

### BACKGROUND ART

When an electronic component, e.g. semiconductor device, is mounted to a substrate, a bump containing solder and formed on an underside of the semiconductor device is jointed with solder to an electrode of the substrate, thereby achieving conduction therebetween. This mounting method is widely used. However, only the solder joint between the bump and the electrode often encounters lack of force to firmly hold the electronic component on the substrate. Thermosetting resin, e.g. epoxy resin, is thus used in general for reinforcing the joint between the electronic component and the substrate.

This resin reinforcement has been done this way: Under-fill resin is filled between the substrate and the electronic component after the component is mounted on the substrate. However, electronic components have been downsized and become micro-sized in recent years, so that it is difficult to fill the resin between the substrate and the component. To overcome this problem, “an advance resin application method” is used as a resin reinforcement method after mounting the component. This method applies, before the mounting, a resin reinforcing member for rigidly mounting the corners, which are to be reinforced, of the electronic component to the substrate together with a joint material, e.g. flux, for soldering the bump, and then hardens the resin reinforcing member after the mounting (refer to Patent Literature PTL 1).

This Patent Literature PTL 1 discloses the following method: Before mounting a semiconductor package to a substrate by the solder joint, apply reinforcing material having a function of flux to multiple places on a mounting surface of the substrate, and after the mounting, thermally harden the reinforcing member to reinforce locally the solder joint sections of the semiconductor package. This resin reinforcing method has an advantage over the previous one, in which the entire underside of the electronic component has been reinforced, because a defective electronic component can be removed with ease from the substrate. Repairs thus can be done simply. On top of that, the solder joint on the bump is not hermetically covered with the resin reinforcing section, so that a solder flush, namely, the solder joint melts and splashes during a next reflow process, can be advantageously prevented.

However, the related art including what is disclosed in Patent Literature PTL 1 has the following problem caused by a positional inaccuracy of applying the reinforcing material before the mounting. The resin reinforcing material is supplied and applied by an application means, e.g. dispenser. At this time, the resin reinforcing material sometimes covers a part of the electrode depending on an accuracy of positional control of application action. When the bump is soldered to the electrode with the resin reinforcing material staying on the electrode, and if the function of flux of the resin reinforcing material is insufficient, the solder joint properties are weakened, so that an excellent solder joint cannot be expected.

This positional inaccuracy that causes the resin reinforcing material to cover the electrode can be prevented by lowering an application speed of the application means; however, in this case the operation becomes slow and the productivity lowers.

As discussed above, the related art has difficulty preventing degradation in solder joint. The degradation is caused by a local cover on the electrode with the resin reinforcing material when the electronic component is mounted to the electrode formed on the substrate, and this electronic component comes with a bump on its underside, and the bump contains solder.

### CITATION LIST

### Patent Literature

PTL 1: Unexamined Japanese Patent Application Publication No. 2008-300538

### SUMMARY OF THE INVENTION

The present invention addresses the problem discussed above, and aims to provide a mounting method that can effectively prevent the solder joint from degrading. The degradation is caused by a local cover on an electrode with a resin reinforcing member when an electronic component with bumps is rigidly mounted to a substrate by using the resin reinforcing member for locally reinforcing the component.

The mounting method of the present invention is to mount an electronic component with bumps containing solder and formed on the underside of the component to electrodes formed on a substrate by soldering the bumps onto the electrodes. The method includes the steps of:

flux supplying step of supplying thermosetting flux to the electrodes or the bumps;

reinforcing member supplying step of supplying a resin reinforcing member, which will not lose shape after being applied to the substrate, to the substrate at positions corresponding to sections, including at least corners, to be reinforced of the electronic component; and after the flux supplying step and reinforcing member supplying step,

component mounting step of mounting an electronic component on the substrate thereby landing the bumps on the electrodes via thermosetting resin and bringing the resin reinforcing member in contact with the sections to be reinforced; and then

reflow step of heating the substrate following a given heat profile, thereby melting and solidifying the bumps to form solder joint sections where the electrodes and the electronic component are joined together, and hardening the thermosetting flux to form a resin reinforcement section that reinforces the solder joint section from the surroundings, and thermally hardening the resin reinforcing member to form a partial reinforcement section that fixes the section to be reinforced onto the substrate.

The thermosetting resin contains a first thermosetting resin including a first active ingredient, and the resin reinforcing member contains a second active ingredient and thixo-component. Those materials are mixed such that the second active ingredient is mixed at a greater mixing ratio than that of the first active ingredient.

Use of this material mixing ratio, i.e. the mixing ratio of the second active ingredient in the resin reinforcing member is greater than that of the first active ingredient in the thermosetting flux, allows the mounting method of the present invention to maintain the solder joint properties between the electrodes and the bumps with the aid of the second active ingredient, even if the resin reinforcing member, of which active ingredient works less effectively, is squeezed out onto the electrodes.

### BRIEF DESCRIPTION OF DRAWINGS

FIG. 1A illustrates a step of a method of mounting an electronic component in accordance with an embodiment of the present invention.

FIG. 1B illustrates a step of the method of mounting an electronic component in accordance with the embodiment.

FIG. 1C illustrates a step of the method of mounting an electronic component in accordance with the embodiment.

FIG. 1D illustrates a step of the method of mounting an electronic component in accordance with the embodiment.

FIG. 1E illustrates a step of the method of mounting an electronic component in accordance with the embodiment.

FIG. 1F illustrates a step of the method of mounting an electronic component in accordance with the embodiment.

FIG. 2 shows an example of the composition of a resin reinforcing member and a thermosetting flux both used in the method of mounting an electronic component in accordance with the embodiment.

FIG. 3A illustrates a step of a method of mounting an electronic component in accordance with the embodiment.

FIG. 3B illustrates a step of the method of mounting an electronic component in accordance with the embodiment.

FIG. 4A illustrates a step of a method of mounting an electronic component in accordance with the embodiment.

FIG. 4B illustrates a step of the method of mounting an electronic component in accordance with the embodiment.

FIG. 5 is an enlarged sectional view of a solder joint section between a bump and an electrode, where the solder joint is carried out in the method of mounting an electronic component in accordance with the embodiment.

### DESCRIPTION OF EMBODIMENT

### First Exemplary Embodiment

The embodiment is demonstrated with reference to the accompanying drawings. The mounting method in accordance with the embodiment is carried out this way: Electronic component 1 with multiple humps 2 containing solder and formed on an underside of component 1 is mounted on substrate 5 by soldering bumps 2 to electrodes 6 formed on substrate 5. In this case, stresses intensively occur at corners of rectangular component 1, whereby a circuit at the solder joint section is sometimes broken. The corners of electronic component 1 thus need to be reinforced by resin reinforcing member 10.

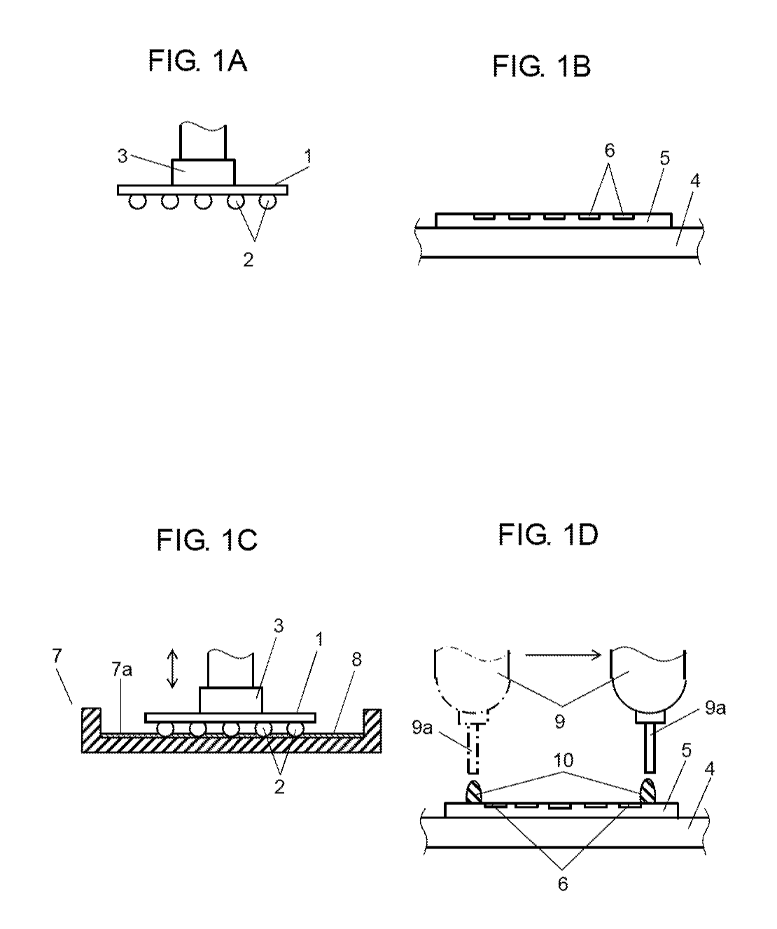

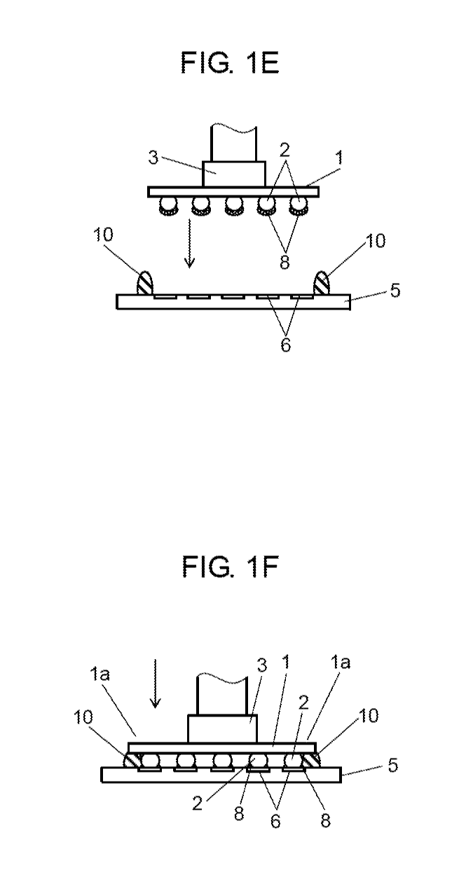

Respective steps of the method are detailed hereinafter. First, as shown in FIG. 1A, electronic component 1 with bumps 2 containing solder and formed on the underside of component 1 is attached and held by component holding tool 3 so that component 1 is taken out from a component supply section (not shown). In parallel with this action, as shown in FIG. 1B, substrate 5 with electrodes 6 formed on its top face is held by substrate holder 4.

Next, as shown in FIG. 1C, component holding tool 3 moves above transfer-printing table 7 for supplying flux to bumps 2. Transfer printing table 7 is a box-shaped container having a flat and smooth transfer printing face 7a which is coated with thermosetting flux 8 in a given thickness.

As shown in FIG. 1C, component holding tool 3 that holds electronic component 1 lowers toward table 7 and then lifts. Bumps 2 on the underside of component 1 are brought into contact with thermosetting flux 8, whereby a given amount of flux 8 is supplied to the lower ends of bumps 2.

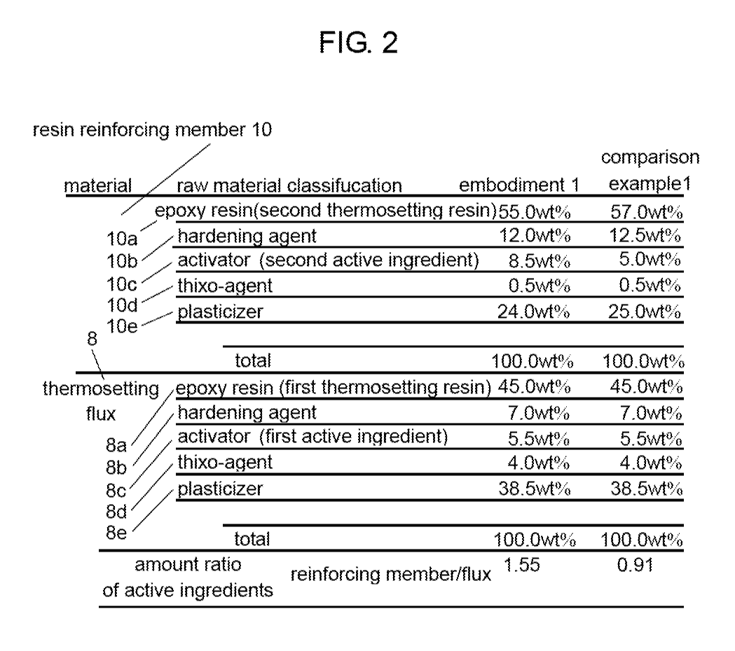

The composition of thermosetting flux 8 is described with reference to FIG. 2. As shown in FIG. 2, flux 8 contains epoxy resin 8a, hardening agent 8b, activator 8c, thixo-agent 8d and plsticizer 8e. Epoxy resin 8a (first thermosetting resin) employs, e.g. epoxy resin of bisphenol-A or bisphenol-F, and is contained at a mixing ratio of 45.0 wt %. Hardening agent. 8b for hardening epoxy resin 8a employs, e.g. imidazole, acid anhydride, hydrazide, or poliythiol, and is contained at a mixing ratio of 7.0 wt %. Activator 8c (first active ingredient) will remove an oxide film formed on the surfaces of electrodes 6 and bumps 2, and activator 8c employs, e.g. organic acid, amine organic acid salt, or amine halogen salt, and is contained at a mixing ratio of 5.5 wt %. Thixo-agent 8d is provided in order to give thixo-properties to thermosetting flux 8, and employs organic thixo-agent, e.g. fatty amide, and is contained at a mixing ratio of 4.0 wt %. Plasticizer 8e is provided in order to give plasticity to thermosetting flux 8. Plasticizer 8e employs modified ethylene glycol, and is contained at a mixing ratio of 38.5 wt %.

As the foregoing composition shows, thermosetting flux 8 is formed of epoxy resin 8a, i.e. first thermosetting resin, and activator 8c, i.e. first active ingredient. Flux 8 can be supplied to bumps 2 by a transfer printing method; however, it can be supplied onto electrodes 6 with a dispenser or by a printing method. In other words, thermosetting flux 8 formed of the first thermosetting resin containing the first active ingredient is supplied to electrodes 6 or bumps 2 (flux supplying step). In parallel with the flux supplying step, resin reinforcing member 10 is supplied to substrate 5 with a dispenser.

As shown in FIG. 1D, dispenser 9 storing resin reinforcing member 10 discharges member 10 from nozzle 9a while it moves above substrate 5. Dispenser 9 supplies resin reinforcing member 10 in a given bank-shape to given places to be reinforced on substrate 5. In this embodiment, the outer peripheral sections including corners of electronic component 1 are assigned to be reinforced. The outer peripheral sections are fixed to substrate 5 via resin reinforcing member 10 for reinforcing the solder joint section. At this time, resin reinforcing member 10 is supplied close to electrodes 6 located at the outermost periphery of electronic component 1.

An example of composition of resin reinforcing member 10 is described with reference to FIG. 2. Resin reinforcing member 10 contains epoxy resin 10a, hardening agent 10b, activator 10c, thixo-agent 10d and plsticizer 10e. Epoxy resin 10a (second thermosetting resin) employs, e.g. epoxy resin of bisphenol-A or bisphenol-F, and is contained at a mixing ratio of 55.0 wt. % in this embodiment. Hardening agent 10b for hardening epoxy resin 10a employs, e.g. imidazole, acid anhydride, hydrazide, or poliythiol, and is contained at a mixing ratio of 12.0 wt %. Activator 10c (second active ingredient) will remove an oxide film formed on the surfaces of electrodes 6 and bumps 2 as activator 8c does, and activator 10c employs, e.g. organic acid, amine organic acid salt, or amine halogen salt, and is contained at a mixing ratio of 8.5 wt. %. Assuming that resin reinforcing member 10 is brought into contact with thermosetting flux 8 on electrodes 6, activator 10c (second active ingredient) employs the same components as those of activator 8c (first active ingredient). If member 10 is brought into contact with flux 8 on electrodes 6, use of the activator common to each other will prevent member 10 or flux 8 from reacting unexpectedly.

Thixo-agent 10d is provided in order to give thixo-properties to resin reinforcing member 10. It employs inorganic thixo-agent having greater thixo-properties the organic one, and is contained at a mixing ratio of 0.5 wt % in resin reinforcing member 10. Plasticizer 10e is provided in order to give plasticity to member 10. Plasticizer 10e employs rubber component which is contained at a mixing ratio of 24.0 wt % in resin reinforcing member 10. In the foregoing composition, the inorganic thixo-agent employs silica fine particles which provide greater thixo-properties, so that the thixo-properties of resin reinforcing member 10 is much greater than that of thermosetting flux 8. Resin reinforcing member 10 applied on substrate 5 does not lose shape from the bank-shape formed on substrate 5, and can maintain the bank-shape in cross section. When electronic component 1 is mounted to substrate 5, this structure allows reinforcement section 1a of electronic component 1 to be brought into contact, without fail, with resin reinforcing member 10 having a bank-shape in cross section.

To be more specific, resin reinforcing member 10, which is free from shape-loss in the applied state on substrate 5, is supplied to the positions corresponding to the sections, including corners, to be reinforced of electronic component 1 (reinforcing member supplying step). Resin reinforcing member 10 is formed of epoxy resin 10a as the second thermosetting resin, activator 10c as the second active ingredient, and thixo-agent 10d as a thixo-component.

As shown in the composition examples of thermosetting flux 8 and resin reinforcing member 10, the mixing ratio of activator 10c in member 10 is set greater than that of activator 8c in flux 8. As shown in FIG. 2, these ratios (activator 10c vs. activator 8c) can be numerically expressed as 1.55. What this number means will be discussed later.

Next, electronic component 1 is mounted to substrate 5. To be more specific, as shown in FIG. 1E, after thermosetting flux 8 is supplied to bumps 2, component holding tool 3 that holds electronic component 1 moves above substrate 5 to which resin reinforcing member 10 has been supplied. Tool 3 then carries out the positioning of humps 2 relative to electrodes 6 on substrate 5, and then tool 3 lowers. Bumps 2 thus land on electrodes 6 via thermosetting flux 8 as shown in FIG. 1F. At the same time reinforcement section 1a of component 1 is brought into contact with resin reinforcing member 10 supplied on substrate 5.

In this step, after the flux supplying step and the reinforcing member supplying step, electronic component 1 is mounted onto substrate 5. Bumps 2 are landed on electrodes 6 via thermosetting flux 8, and reinforcement section 1a of component 1 is brought into contact with resin reinforcing member 10 supplied on substrate 5 (component mounting step).

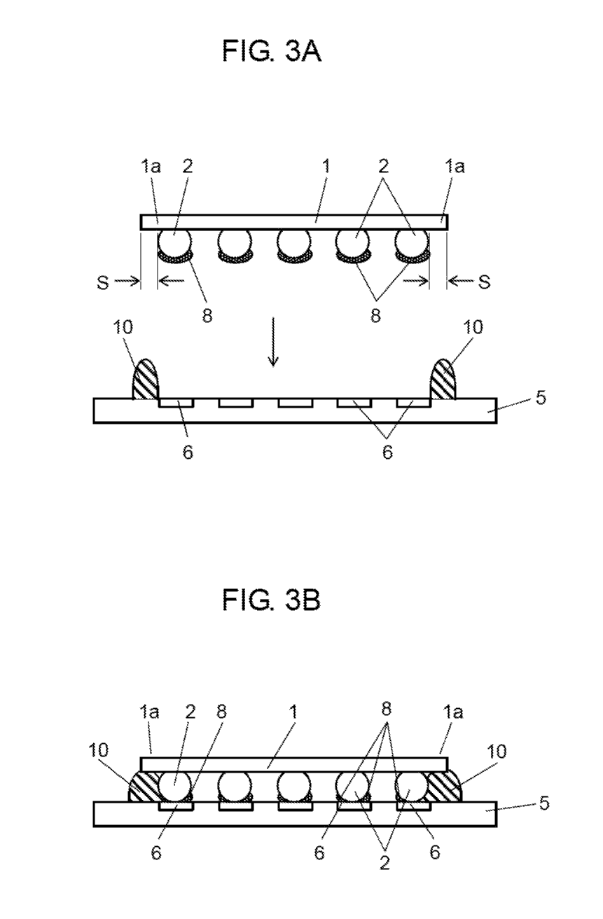

The behavior of resin reinforcing member 10 during the component mounting step is described with reference to FIG. 3. Since electronic component 1, to be mounted, is a small sized component, as shown in FIG. 3A, space S between bump 2 at the outermost periphery and an outer edge of component 1 is so small that a margin to which resin reinforcing member 10 is brought into contact for reinforcement is narrow. Resin reinforcing member 10 is thus supplied onto substrate 5 at places closer to electrodes 6, and among others, member 10 is applied to a place much closer to the outermost electrode 6. When component 1 is mounted onto substrate 5, as shown in FIG. 3B, resin reinforcing member 10 depressed by reinforcement section 1a of component 1 is stretched inward on the top face of substrate 5, and parts of stretched member 10 cover a top face of electrode 6 partially, so that stretched member 10 stays between the underside of bump 2 and the top face of electrode 6. Substrate 5 in this state is then transferred to a reflow apparatus.

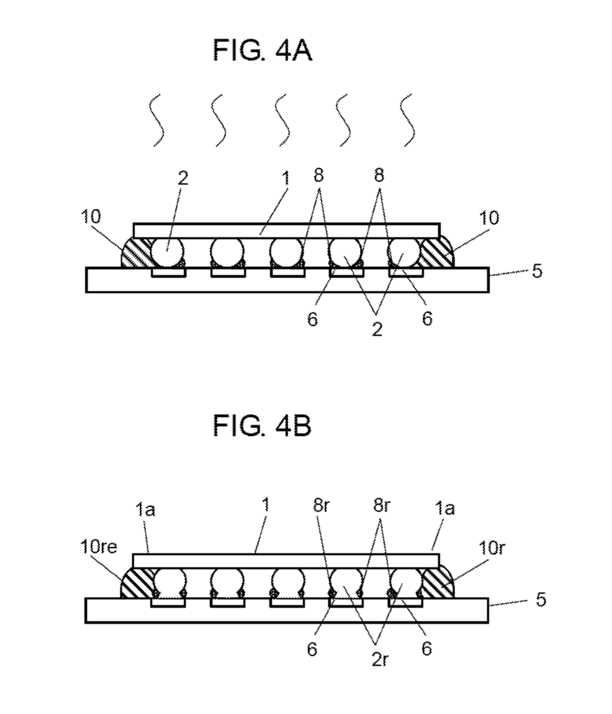

As shown in FIG. 4A, substrate 5 is heated following the given heating profile, whereby bumps 2 formed of solder are melted and solidified for being bonded to electrodes 6 with solder, and solder joint sections 2r are thus formed. At this time, the active ingredient contained in thermosetting flux 8 removes oxide film formed on the surfaces of bumps 2 and electrodes 6, so that the melted solder tends to spread on electrodes 6, and as a result, excellent solder joint can be achieved. Epoxy resin 8a contained in flux 8 is thermally hardened to form resin reinforcement sections 8r that can reinforce solder joint sections 2r from the surroundings. On top of that, resin reinforcing member 10 is thermally hardened to form partial reinforcement section 10r that fixes reinforcement section 1a to substrate 5.

In other words, the reflow step discussed above heats substrate 5 according to the given heating profile after the component mounting step, thereby melting and solidifying bumps 2 to form solder joint sections 2r that bonds electrodes 6 to electronic component 1. At the same time, thermosetting flux 8 is hardened to form resin reinforcement sections 8r that reinforces solder joint sections 2r from the surroundings. On top of that, resin reinforcing member 10 is thermally hardened to form partial reinforcement section 10r that fixes reinforcement section 1a to substrate 5 (reflow step).

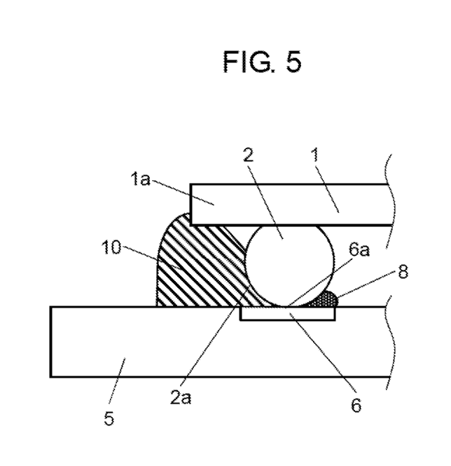

Next, the behavior of resin reinforcing member 10 during the foregoing reflow step is described with reference to FIG. 5, and how resin reinforcing member 10 works in the solder joint between bumps 2 and electrodes 6 is also demonstrated hereinafter. As discussed above, resin reinforcing member 10 depressed in the component mounting step covers in part the top face 6a of electrode 6 partially, so that the reflow step is carried out while resin reinforcing member 10 stays between the underside of bump 2 and top face 6a of electrode 6. At this time, resin reinforcing member 10 contains activator 10c at a greater mixing ratio than that of activator 8c in flux 8. This structure allows resin reinforcing member 10, which is a flow resistance material having high thxio-properties and resists flowing, to give sufficient activating action to top face 6a of electrode 6 and surface 2a of bump 2.

In other words, resin reinforcing member 10 to be supplied for fixing reinforcement section 1a of electronic component 1 to substrate 5 needs to have high thixo-properties that prevents the shape-loss. Therefore, among the active ingredients contained in resin reinforcing member 10, only the active ingredient included at the sections brought into contact with surface 2a and top face 6a will enhance the junction properties of the solder junction. To be more specific, the active ingredient of resin reinforcing member 10 works less effectively than that of thermosetting flux 8, because the composition of flux 8 allows flux 8 to be free-flowing liquid on top face 6a. To obtain an excellent junction properties of solder junction between electrode 6 and bump 2 located closely to the reinforcement section to which resin reinforcing member 10 is supplied, the mixing ratio of activator 10c in resin reinforcing member 10 needs to be higher than that of activator 8c in thermosetting flux 8.

In this embodiment as shown in FIG. 2, the mixing ratio of activator 10c (second active ingredient) in resin reinforcing member 10 is divided by the mixing ratio of activator 8c (first active ingredient) in thermosetting flux 8, and the division result is an amount ratio of these active ingredients, i.e. equals 1.55. It is thus preferable to maintain the amount ratio of these active ingredients between 1.2 and 1.8 (inclusive) in order to obtain the excellent junction properties of the solder junction.

Setting the mixing ratio of activator 10c in resin reinforcing member 10 at 1.2 times as much as that of activator 8c in thermosetting resin 8 will allow the oxide film removing capability of resin reinforcing member 10 to be generally equal to that of flux 8. If the mixing ratio is set less than 1.2 times, the oxide film removing capability of resin reinforcing member 10 becomes smaller than that of flux 8, so that the junction properties between electrode 6 and bump 2 is insufficient. A greater mixing ratio of activator 10c will increase the oxide film removing capability; however, if it goes too far, preservation stability will be degraded or migration will occur, so that it is preferable that the mixing ratio should be not greater than 1.8 times as much as that of activator 8c in flux 8.

As shown in FIG. 2, comparison example 1 exhibits a composition of resin reinforcing member 10 and thermosetting flux 8. In this composition, the amount ratio of the active ingredients discussed above is 0.91, namely, out of the range from 1.2 to 1.8 (inclusive). In other words, this comparison example 1 employs thermosetting flux 8 having the same composition as the embodiment 1 and resin reinforcing member 10 of which mixing ratio of activator 10c is lowered to 5.0 wt % from that of embodiment 1. The member 10 and flux 8 of this comparison example 1 are used in the steps of mounting the component as shown in FIG. 1-FIG. 4, and this experiment, proves that the junction properties of solder junction between electrode 6 and bump 2 located close to the reinforcement section, to which resin reinforcing member 10 is supplied, cannot be obtained at a satisfactory level.

As discussed above, the method of mounting an electronic component in accordance with this embodiment mounts electronic component 1 with bumps 2 containing solder and formed on the underside of component 1 by bonding bumps 2 to electrodes 6 formed on substrate 5 through a solder junction. This method includes the steps of flux supplying step, reinforcing member supplying step, component mounting step, and reflow step to be carried out after the component mounting step.

The flux supplying step supplies thermosetting flux 8 to electrodes 6 or bumps 2. The reinforcing member supplying step supplies resin reinforcing member 10, which can stay free from losing shape when it is applied on substrate 5, to places corresponding to reinforcement sections 1a including at least corners of electronic component 1 on substrate 5.

The component mounting step mounts electronic component 1 to substrate 5 after the flux supplying step and the reinforcing member supplying step, and lands bumps 2 on electrodes 6 via thermosetting flux 8, and at the same time, reinforcement sections 1a are brought into contact with resin reinforcing member 10. In other words, bumps 2 are landed on electrodes 6 via thermosetting flux 8 which is formed of epoxy resin 8a (the first thermosetting resin) containing activator 8c (first active ingredient). On top of that, reinforcement sections 1a of component 1 are brought into contact with resin reinforcing member 10 which is formed of epoxy resin 10a (second thermosetting resin) containing activator 10c (second active ingredient),

The reflow step heats substrate 5 following the given heating profile after the component mounting step, whereby bumps 2 are melted and solidified to form solder joint sections where electrodes 6 are bonded to electronic component 1 with solder. At the same time, thermosetting flux 8 is hardened to form resin reinforcement section 8r that will reinforce the solder joint sections from the surroundings. On top of that, resin reinforcing member 10 is thermally hardened to form partial reinforcement sections that will fix reinforcement sections 1a to substrate 5.

In other words, after component 1 is mounted on substrate 5, which is then heated to form solder joint section 2r, thereby bonding bumps 2 to electrodes 6. On top of that, resin reinforcement section 8r is formed for reinforcing this solder joint section 2r from the surroundings. Thermosetting flux 8 used in this embodiment is formed of the first thermosetting resin containing a first active ingredient, and resin reinforcing member 10 used in this embodiment is formed of the second active ingredient and a thixo-component. The mixing ratio of activator 10c in resin reinforcing member 10 is set greater than that of activator 8c in thermosetting flux 8.

Even if resin reinforcing member 10, of which active ingredient works less effectively, is squeezed out on electrodes 6 due to a positional deviation of supplied resin reinforcing member 10 or stretching by electronic component 1 when it is mounted, activator 10c included at the sections brought into contact with bumps 2 or electrodes 6 will ensure the solder joint between electrodes 6 and humps 2. When resin reinforcing member 10 locally covers electrode 6, the joint properties of solder joint between bumps 2 and electrodes 6 at the reinforcement section are degraded; however, the foregoing structure prevents the degradation effectively.

### INDUSTRIAL APPLICABILITY

The mounting method of an electronic component of the present invention rigidly mounts an electronic component having humps to a substrate and also reinforces the component locally with a resin reinforcing member. The method advantageously prevents the joint properties of solder joint from degrading caused by a local cover on the electrode with the rein reinforcing member. This method is useful in the field of manufacturing a printed wired assembly where the electronic component with bumps is soldered to the substrate.

### REFERENCE MARKS IN THE DRAWINGS

1 electronic component
1a reinforcement section
2 bump
2r solder joint section
5 substrate
6 electrode
7 transfer printing table
8 thermosetting flux
8a, 10a epoxy resin
8b, 10b hardening agent
8c, 10c activator
8d, 10d thixo-agent
8e, 10e plasticizer
8r resin reinforcement section
10 resin reinforcing member
10r partial reinforcement section

1. A method of mounting an electronic component, having a bump containing solder and formed on an underside of the component, by bonding the bump to an electrode formed on a substrate through solder junction, the method comprising the steps of:
a flux supplying step of supplying thermosetting flux to the electrode or the bump;
a reinforcing member supplying step of supplying a resin reinforcing member, free from shape-loss when the member is applied on the substrate, to a place of the substrate corresponding to a reinforcement section including at least corners of the electric component; and after the flux supplying step and the reinforcing member supplying step,
a component mounting step of mounting the electronic component on the substrate, and landing the bump onto the electrode via the thermosetting flux, and bringing the reinforcement section into contact with the resin reinforcing member; and then
a reflow step of heating the substrate according to a given heating profile to melt and solidify the bump, so that a solder junction section that bonds the electrode to the component is formed, and hardening the thermosetting flux to form a resin reinforcement section that reinforces the solder junction section from surroundings, and thermally hardening the resin reinforcing member to form a partial reinforcement section that fixes the reinforcement section to the substrate,
wherein the thermosetting flux is formed of a first thermosetting resin containing a first active ingredient, and the resin reinforcing member is formed of a second active ingredient and a thixo-component,
wherein a mixing ratio of the second active ingredient in the resin reinforcing member is greater than that of the first active ingredient in the thermosetting flux.

2. The method of claim 1, wherein the resin reinforcing member has greater thixo-properties than the thermosetting flux.

3. The method of claim 1, wherein the mixing ratio of the second active ingredient in the resin reinforcing member is divided by the mixing ratio of the first active ingredient in the thermosetting flux, and a division result is an amount ratio of those active ingredients, and the amount ratio falls within a range from 1.2 to 1.8 (inclusive).

4. The method of claim 1, wherein the first active ingredient has the same component as the second active ingredient.
